(19) United States
(12) Patent Application Publication
(10) Pub. No.: US 2025/0149856 A1
(43) Pub. Date: May 8, 2025

(54) OPTOELECTRONIC SEMICONDUCTOR LASER COMPONENT AND OPTOELECTRONIC ARRANGEMENT

(71) Applicant: ams-OSRAM INTERNATIONAL GmbH, Regensburg (DE)

(72) Inventors: Hubert HALBRITTER, Dietfurt (DE); Adrian Stefan AVRAMESCU, Regensburg (DE); Christoph EICHLER, Donaustauf (DE)

(73) Assignee: ams-OSRAM International GmbH, Regensburg (DE)

(21) Appl. No.: 18/836,990

(22) PCT Filed: Dec. 13, 2022
(86) PCT No.: PCT/EP2022/085630

§ 371 Date: Aug. 8, 2024

(30) Foreign Application Priority Data
Feb. 10, 2022 (DE) 102022103128.4

(51) Int. Cl. H01S 5/11

(52) U.S. Cl. CPC H01S 5/11

(57) ABSTRACT

The invention relates to an optoelectronic semiconductor laser component. The optoelectronic semiconductor laser component includes an epitaxial semiconductor layer sequence having an active region which is designed to generate first electromagnetic radiation in a first wavelength range. The optoelectronic semiconductor laser component further includes a photonic semiconductor layer which forms a two-dimensional photonic crystal and is designed to form a resonator for the first electromagnetic radiation, and a conversion element which is designed to convert the first electromagnetic radiation into second electromagnetic radiation in a second wavelength range. The emission direction is oriented transversely to the main plane of extent of the epitaxial semiconductor layer sequence. The first electromagnetic radiation exits from the photonic semiconductor layer in the emission direction. The first wavelength range is in the blue or ultraviolet spectral range. The invention also relates to an optoelectronic arrangement.

### CROSS-REFERENCE TO RELATED APPLICATIONS

The present application is a national stage entry from International Application No. PCT/EP2022/085630, filed on Dec. 13, 2022, published as International Publication No. WO 2023/151851 A1 on Aug. 17, 2023, and claims priority to German Patent Application No. 10 2022 103 128.4, filed Feb. 10, 2022, the disclosures of all of which are hereby incorporated by reference in their entireties.

### FIELD

An optoelectronic semiconductor laser component and an optoelectronic arrangement are disclosed. The optoelectronic semiconductor laser component and the optoelectronic arrangement are in particular configured to generate electromagnetic radiation, for example light that is perceptible to the human eye.

### BACKGROUND

One task to be solved is to specify an optoelectronic semiconductor laser component which has a particularly high luminance.

A further task to be solved is to specify an optoelectronic arrangement which has a particularly high luminance. The optoelectronic arrangement comprises at least two optoelectronic semiconductor laser components.

These tasks are solved by devices according to the independent patent claims. Advantageous embodiments and further embodiments of the devices are the subject of the dependent patent claims and are also apparent from the following description and the figures.

The semiconductor laser component is intended in particular for the emission of coherent electromagnetic radiation.

### SUMMARY

According to at least one embodiment, the optoelectronic semiconductor laser component comprises an epitaxial semiconductor layer sequence having an active region configured to generate a first electromagnetic radiation of a first wavelength range.

In particular, the epitaxial semiconductor layer sequence has a stacking direction along which the semiconductor layers of the epitaxial semiconductor layer sequence are epitaxially grown. The stacking direction is perpendicular to a main extension plane of the epitaxial semiconductor layer sequence.

The active region has in particular a pn junction, a double heterostructure, a single quantum well structure (SQW) or a multi-quantum well structure (MQW) for the generation of radiation.

According to at least one embodiment of the optoelectronic semiconductor laser component, the epitaxial semiconductor layer sequence and in particular the active region is based on a nitride compound semiconductor material or is formed by a nitride compound semiconductor material. Nitride compound semiconductor materials are compound semiconductor materials that contain nitrogen, such as the materials from the material system InₓAl_{y}Ga_{1-x-y}N with 0≤x≤1, 0≤y≤1 and x+y≤1. As a rule, an active layer that is based on a nitride compound semiconductor material or is formed from a nitride compound semiconductor material is set up to generate blue or ultraviolet light.

According to at least one embodiment, the optoelectronic semiconductor laser component comprises a photonic semiconductor layer forming a two-dimensional photonic crystal and configured to form a resonator for the first electromagnetic radiation.

In particular, the photonic semiconductor layer is based on the same material system as the epitaxial semiconductor layer sequence. For example, the photonic semiconductor layer is based on a nitride compound semiconductor material or is formed from a nitride compound semiconductor material. The photonic semiconductor layer can be an epitaxially grown semiconductor layer that is subsequently provided with a structure to form the photonic crystal.

Furthermore, it is also possible that the photonic semiconductor layer comprises a different material or is formed from a different material than the epitaxial semiconductor layer sequence. For example, the photonic semiconductor layer is based on a transparent conductive oxide (TCO for short) or has one or more TCOs.

Transparent conductive oxides are usually metal oxides such as zinc oxide, tin oxide, cadmium oxide, titanium oxide, indium oxide or indium tin oxide (ITO). In addition to binary metal oxygen compounds, such as Zno, SnO₂ or In₂O₃, ternary metal oxygen compounds, such as Zn₂SnO₄, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p- and n-doped.

The photonic crystal has an optical band gap for photons, equivalent to the electronic band gap of semiconductors. Photons with energies within the photonic band gap cannot propagate in the photonic crystal and are reflected by the photonic crystal. The photonic bandgap in the photonic crystal is formed due to periodic structures of at least two different materials which the photonic crystal comprises or from which the photonic crystal is formed. The dimension of the photonic crystal is determined by the dimension of the periodicity of the structure. In particular, the two-dimensional photonic crystal comprises structures that are periodic in two directions in space.

For example, the two-dimensional photonic crystal has a structure formed from air-filled, periodically arranged recesses. The recesses can, for example, be columnar in shape and arranged parallel to the stacking direction of the semiconductor layer sequence. Distances between directly adjacent recesses and/or diameters of the recesses are in particular an integer multiple of the fourth part of the wavelength of the first electromagnetic radiation.

The active region is arranged to generate a first electromagnetic radiation of a first wavelength range. In particular, the first electromagnetic radiation comprises a global intensity maximum at a first peak wavelength within the first wavelength range.

According to at least one embodiment, the optoelectronic semiconductor laser component comprises a conversion element which is configured to convert the first electromagnetic radiation into a second electromagnetic radiation of a second wavelength range. In particular, the conversion element effects a conversion towards longer wavelengths. In other words, a second peak wavelength of the second electromagnetic radiation is greater than the first peak wavelength of the first electromagnetic radiation. For example, a mixed radiation comprising a portion of the first electromagnetic radiation and a portion of the second electromagnetic radiation emerges from the optoelectronic semiconductor laser component. The mixed radiation has a white color, for example. Alternatively, it is possible to convert the first electromagnetic radiation as completely as possible into second electromagnetic radiation.

According to at least one embodiment of the optoelectronic semiconductor laser component, the first electromagnetic radiation propagates within the resonator parallel to a main extension plane of the semiconductor layer sequence. Preferably, a large area is thus available for forming the resonator. The main extension plane extends transversely, in particular perpendicular to the stacking direction of the epitaxial semiconductor layer sequence. For example, the resonator comprises at least one optical axis that extends along a main extension plane of the epitaxial semiconductor layer sequence.

According to at least one embodiment of the optoelectronic semiconductor laser component, an emission direction is oriented transverse to the main extension plane of the semiconductor layer sequence. The emission direction is the direction in which a majority of the electromagnetic radiation is emitted from the optoelectronic semiconductor laser component. Preferably, the conversion element is arranged downstream of the epitaxial semiconductor layer sequence in the emission direction.

According to at least one embodiment of the optoelectronic semiconductor laser component, the first electromagnetic radiation emerges from the photonic semiconductor layer in the emission direction. In other words, the first electromagnetic radiation emerges from the photonic semiconductor layer transverse to the main extension plane of the semiconductor layer sequence.

According to at least one embodiment of the optoelectronic semiconductor laser component, the first wavelength range is in the blue or ultraviolet spectral range. A first electromagnetic radiation in the blue or ultraviolet spectral range is particularly suitable for conversion into a second electromagnetic radiation. In particular, a white color impression can thus be produced in an observer of the mixed radiation comprising the first and second electromagnetic radiation. Furthermore, it is also possible to generate differently colored electromagnetic radiation as mixed radiation or by complete conversion into the second wavelength range.

According to at least one embodiment, the optoelectronic semiconductor laser component comprises:
an epitaxial semiconductor layer sequence having an active region configured to generate a first electromagnetic radiation of a first wavelength range,
a photonic semiconductor layer forming a two-dimensional photonic crystal and configured to form a resonator for the first electromagnetic radiation, and
a conversion element configured to convert the first electromagnetic radiation into a second electromagnetic radiation of a second wavelength range, wherein
the first electromagnetic radiation propagates within the resonator parallel to a main extension plane of the epitaxial semiconductor layer sequence,
an emission direction is oriented transverse to the main extension plane of the epitaxial semiconductor layer sequence,
the first electromagnetic radiation emerges from the photonic semiconductor layer in the emission direction, and
the first wavelength range is in the blue or ultraviolet spectral range.

An optoelectronic semiconductor laser component described here is based on the following considerations, among others: Laser components are often used in the manufacture of semiconductor components with very high luminance levels. Due to the mirrors required in conventional laser components, manufacturing costs are increased and higher demands are placed on hermetic encapsulation to protect the mirrors. Furthermore, it is difficult to combine a laser component directly with a conversion element to form a white-emitting light source, as a very high luminance can also lead to inhomogeneous excitation of a conversion element.

The optoelectronic semiconductor laser component described herein makes use, inter alia, of the idea of using a semiconductor laser component described herein with a photonic semiconductor layer and a conversion element. The photonic semiconductor layer enables an advantageously high luminance, which is particularly homogeneously distributed on the conversion element. Furthermore, the photonic semiconductor layer eliminates the need for sensitive mirrors on the outer surfaces of the semiconductor laser component. This means that hermetic encapsulation of the semiconductor laser component is not absolutely necessary.

According to at least one embodiment of the optoelectronic semiconductor laser component, a growth substrate is arranged directly on the semiconductor layer sequence and the conversion element is arranged on the growth substrate on a side of the growth substrate facing away from the semiconductor layer sequence. In other words, the growth substrate is arranged between the semiconductor layer sequence and the conversion element. The layers of the epitaxial semiconductor layer sequence are grown on the growth substrate. The growth substrate is preferably formed with the material of the semiconductor layer sequence. For example, the growth substrate is formed with gallium nitride or sapphire. In particular, the growth substrate is permeable to the first electromagnetic radiation.

According to at least one embodiment of the optoelectronic semiconductor laser component, the growth substrate has pores at least in some sections. In particular, the pores have an average diameter of at least 10 nm, preferably of at least 100 nm, particularly preferably of at least 200 nm.

According to at least one embodiment of the optoelectronic semiconductor laser component, the growth substrate has a thickness of at most 100 μm, in particular of at most 50 μm. Preferably, the growth substrate is thinned to this thickness and comprises traces of an ablation process. A thin growth substrate enables particularly unhindered transmission of the first electromagnetic radiation through the growth substrate.

According to at least one embodiment of the optoelectronic semiconductor laser component, the conversion element is at least partially embedded in the growth substrate. For example, the conversion element comprises quantum dots or nano dashes embedded in pores of the growth substrate. Advantageously, this eliminates a refractive index jump between the conversion element and the growth substrate.

According to at least one embodiment of the optoelectronic semiconductor laser component, the growth substrate is formed with a nitride semiconductor compound material, preferably with gallium nitride. Large pores can be advantageously introduced into a nitride compound semiconductor material. For example, pores and fine channels can be introduced into the growth substrate using a suitable etching solution.

According to at least one embodiment of the optoelectronic semiconductor laser component, the photonic semiconductor layer comprises a contact layer having a first contact region and a second contact region, wherein the first contact region is formed with a material different from the second contact region. In particular, the first contact region is arranged along a main extension plane of the resonator. The second contact region is preferably arranged on a side of the photonic semiconductor layer facing away from the semiconductor layer sequence. Particularly preferably, the second contact region extends up to and adjoins the semiconductor layer sequence.

In particular, the first contact region has a higher optical radiation permeability for the first electromagnetic radiation than the second contact region. A high radiation permeability advantageously results in low optical losses in the resonator of the photonic semiconductor layer.

In particular, the second contact region has a higher electrical conductivity than the first contact region. High electric conductivity results in an advantageously low electrical resistance for the injection of charge carriers into the semiconductor layer sequence. For example, the first and second contact regions are formed with different TCO materials.

According to at least one embodiment of the optoelectronic semiconductor laser component, the semiconductor layer sequence comprises a first semiconductor region of a first conductivity and a second semiconductor region of a second conductivity, the second semiconductor region has a p-type conductivity, and the second semiconductor region is disposed between the active region and the photonic semiconductor layer. In other words, the photonic semiconductor layer is adjacent to the second semiconductor region.

The first semiconductor region and the second semiconductor region preferably comprise cladding structures, waveguide structures and other structures for electrical contacting of the semiconductor layer sequence. The first conductivity is preferably different from the second conductivity. In particular, the first conductivity is an n-type conductivity and the second conductivity is a p-type conductivity.

According to at least one embodiment of the optoelectronic semiconductor laser component, the epitaxial semiconductor layer sequence is arranged on a carrier, the optoelectronic semiconductor laser component is free of a growth substrate and the conversion element is arranged on a side of the epitaxial semiconductor layer sequence opposite the carrier. The absence of a growth substrate results in particularly undisturbed emission of the first electromagnetic radiation. The carrier is formed, for example, with one of the following materials: Diamond, Si, Ge, SiC, AlN, Direct Bonded Copper (DBC). Preferably, the carrier is mechanically self-supporting and provides the optoelectronic semiconductor laser component with sufficient mechanical stability.

According to at least one embodiment of the optoelectronic semiconductor laser component, the photonic semiconductor layer comprises a radiation permeable functional layer and a plurality of recesses, wherein the functional layer is at least partially arranged between the recesses and the semiconductor layer sequence. In particular, the functional layer is arranged in the main extension plane of the resonator of the photonic semiconductor layer.

According to at least one embodiment of the optoelectronic semiconductor laser component, the functional layer is formed with a semiconductor material. In particular, the functional layer is formed with the same semiconductor material as the semiconductor layer sequence. Advantageously, a refractive index jump between the semiconductor layer sequence and the functional layer can thus be avoided.

According to at least one embodiment of the optoelectronic semiconductor laser component, the functional layer comprises at least a first marking layer. The marking layer is formed in particular with the material of the functional layer and has a different doping. For example, the marking layer can be recognized in a plasma etching process. By means of the marking layer, better accuracy in the production of recesses with a desired depth in the photonic semiconductor layer is possible.

According to at least one embodiment of the optoelectronic semiconductor laser component, the semiconductor layer sequence comprises a first semiconductor region of a first conductivity and a second semiconductor region of a second conductivity, the first semiconductor region has an n-conductivity, and the first semiconductor region is disposed between the active region and the photonic semiconductor layer. In other words, the photonic semiconductor layer is adjacent to the first semiconductor region. An injection of electrical charge carriers into the first semiconductor region preferably occurs via the photonic semiconductor layer.

According to at least one embodiment of the optoelectronic semiconductor laser component, the conversion element is arranged at a distance from the semiconductor layer sequence. The conversion element is thus a so-called near-to-chip converter.

The conversion element comprises, for example, a frame body which is mounted on the optoelectronic semiconductor laser component via an alignment element. The frame body preferably surrounds the edge of the conversion element. In particular, the alignment element is in contact with the semiconductor layer sequence. The alignment element comprises, for example, a body produced by means of additive manufacturing. Preferably, the alignment element is made of metal.

Advantageously, the conversion element is not in direct contact with the semiconductor layer sequence and can have a particularly large expansion in the emission direction. In particular, the conversion element has an expansion in the emission direction of more than 100 μm and preferably more than 1000 μm.

The distance of the conversion element from the semiconductor layer sequence in the emission direction is preferably within the coherence length of the first electromagnetic radiation. In particular, the distance is at least 1 μm, preferably at least 10 um and particularly preferably at least 50 μm.

According to at least one embodiment of the optoelectronic semiconductor laser component, the depths of the recesses differ by at least 10 nm, in particular by at least 100 nm. The depth of the recesses corresponds to an expansion of the recesses parallel to the emission direction. Different depths can be used to reduce undesirable periodicity in the photonic semiconductor layer.

According to at least one embodiment of the optoelectronic semiconductor laser component, the conversion element comprises a plurality of conversion regions embedded in a shaped body. The conversion regions are formed in particular with quantum dots or nano dashes. Quantum dots and nano dashes are particularly easy to introduce into small pores of a porous material. Here and in the following, porous means a material with pores of an average size of at least 10 nm, preferably at least 100 nm, particularly preferably at least 200 nm. In particular, foreign materials can be introduced into the pores of the growth substrate. The shaped body is advantageously formed with a radiation permeable material. For example, the shaped body is formed with gallium nitride.

According to at least one embodiment of the optoelectronic semiconductor laser component, a wavelength-selective filter element is arranged between the semiconductor layer sequence and the conversion element. The filter element preferably has a higher permeability for the first electromagnetic radiation than for the second electromagnetic radiation. In particular, the filter element is permeable for the first electromagnetic radiation and reflective/reflecting for the second electromagnetic radiation. Advantageously, this increases the proportion of the second electromagnetic radiation in the mixed radiation emitted. For example, the first electromagnetic radiation is converted as completely as possible into second electromagnetic radiation.

According to at least one embodiment of the optoelectronic semiconductor laser component, an optical element is arranged downstream of the conversion element in the emission direction. The optical element is, for example, a lens for beam shaping. In particular, the optical element is a collimating lens for the electromagnetic radiation emitted from the semiconductor laser component.

According to at least one embodiment of the optoelectronic semiconductor laser component, an anti-reflective coating is arranged between the conversion element and the semiconductor layer sequence. An anti-reflective coating increases, for example, a proportion of first electromagnetic radiation entering the conversion element.

According to at least one embodiment of the optoelectronic semiconductor laser component, the conversion element has a lateral expansion which corresponds to at least a single and at most five times the diameter of a beam of electromagnetic radiation emitted by the photonic semiconductor layer. This enables particularly good utilization of the first electromagnetic radiation.

According to at least one embodiment of the optoelectronic semiconductor laser component, the conversion element is formed with a ceramic. A conversion element formed with ceramic can be manufactured in a separate manufacturing process. In particular, the conversion element is mechanically self-supporting.

According to at least one embodiment of the optoelectronic semiconductor laser component, a reflector is arranged on a side of the semiconductor layer sequence opposite the conversion element. Preferably, the reflector comprises a plurality of first and second reflective layers having different refractive indices. In particular, the first and second reflective layers are arranged in an alternating order to form a Distributed Bragg Reflector (DBR) for the first electromagnetic radiation. Alternatively, the reflector comprises a metal having a high optical reflectivity for the first electromagnetic radiation. For example, the reflector is formed with one of the following metals: aluminum, silver, gold. Advantageously, a radiation permeable dielectric is arranged between the reflector and the semiconductor layer sequence.

An optoelectronic arrangement is further disclosed. In particular, the optoelectronic arrangement comprises at least two of the optoelectronic semiconductor laser components described herein. That is, all features disclosed in connection with the optoelectronic semiconductor laser component are also disclosed for the optoelectronic arrangement and vice versa.

According to at least one embodiment, the optoelectronic arrangement comprises at least two optoelectronic semiconductor laser components, wherein the semiconductor laser components have a contiguous epitaxial semiconductor layer sequence. In particular, the semiconductor laser components can be controlled individually. The formation of several semiconductor laser components in an epitaxial semiconductor layer sequence enables a particularly simple production of an optoelectronic arrangement with a high density of individually controllable semiconductor laser components.

According to at least one embodiment of the optoelectronic arrangement, the wavelengths of the second electromagnetic radiations of the semiconductor laser components differ from each other by at least 5 nm, preferably by at least 10 nm. Unwanted interference effects, such as speckles, can thus be reduced in a targeted manner.

An optoelectronic semiconductor laser component described here is particularly suitable for use as a compact light source with a high luminance, for example in headlights for motor vehicles or stage lighting.

Further advantages and advantageous configurations and further embodiments of the optoelectronic semiconductor laser component and the optoelectronic arrangement result from the following exemplary embodiments shown in connection with the figures.

### BRIEF DESCRIPTION OF THE DRAWINGS

FIG. 1 a schematic sectional view of an optoelectronic semiconductor laser component described here according to a first exemplary embodiment,

FIG. 2 a schematic sectional view of an optoelectronic semiconductor laser component described herein according to a second exemplary embodiment,

FIG. 3 a schematic sectional view of an optoelectronic semiconductor laser component described here according to a third exemplary embodiment,

FIG. 4 a schematic sectional view of an optoelectronic semiconductor laser component described herein according to a fourth exemplary embodiment,

FIG. 5 a schematic sectional view of an optoelectronic semiconductor laser component described herein according to a fifth embodiment,

FIG. 6 a schematic sectional view of an optoelectronic semiconductor laser component described herein according to a sixth exemplary embodiment,

FIG. 7 a schematic sectional view of an optoelectronic semiconductor laser component described herein according to a seventh embodiment,

FIG. 8 a schematic sectional view of an optoelectronic semiconductor laser component described herein according to an eighth embodiment, and

FIG. 9 a schematic sectional view of an optoelectronic arrangement described here according to a first exemplary embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

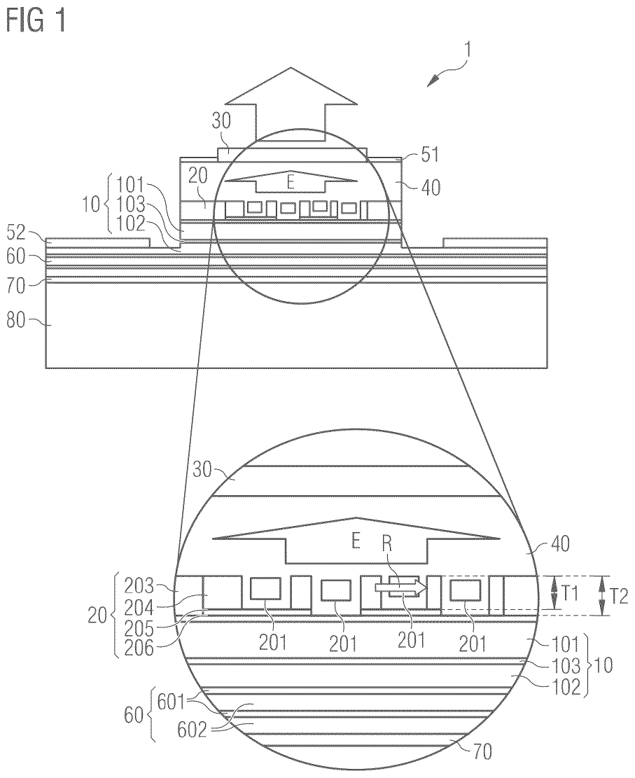

FIG. 1 shows a schematic sectional view of an optoelectronic semiconductor laser component 1 described herein according to a first exemplary embodiment. The optoelectronic semiconductor laser component 1 comprises an epitaxial semiconductor layer sequence 10 with an active region 103, which is arranged between a first semiconductor region 101 of a first conductivity and a second semiconductor region 102 of a second conductivity and is configured to generate a first electromagnetic radiation of a first wavelength range. The first conductivity is an n-conductivity and the second conductivity is a p-conductivity. The first semiconductor region 101 and the second semiconductor region 102 preferably comprise optical cladding structures and waveguide structures.

The epitaxial semiconductor layer sequence 10 has a stacking direction along which the semiconductor layers of the epitaxial semiconductor layer sequence 10 are epitaxially grown. The stacking direction is perpendicular to a main extension plane of the epitaxial semiconductor layer sequence 10.

The optoelectronic semiconductor laser component 1 further comprises a photonic semiconductor layer 20 comprising a two-dimensional photonic crystal having a plurality of recesses 201 and configured to form a resonator for the first electromagnetic radiation. The resonator has at least one optical axis R along a main extension plane of the epitaxial semiconductor layer sequence.

The photonic semiconductor layer 20 comprises a radiation permeable functional layer 204. The functional layer 204 is arranged at least partially between the recesses 201 and the semiconductor layer sequence 10. In particular, the functional layer 204 is arranged in the main extension plane of the resonator of the photonic semiconductor layer 20. The functional layer 204 is formed with a semiconductor material, in particular a nitride compound semiconductor material. Preferably, the functional layer 204 is formed with the same semiconductor material as the semiconductor layer sequence 10. Advantageously, a refractive index jump between the semiconductor layer sequence 10 and the functional layer 204 can thus be omitted.

The functional layer 204 comprises a multilayer structure. The functional layer 204 comprises a first marking layer 205 and a second marking layer 206. The marking layers 205, 206 are formed in particular with the material of the functional layer 204 and have a different doping. For example, the marking layers 205, 206 can be recognized in a plasma etching process. By means of the marking layers 205, 206, a better accuracy in the production of the recesses 201 with a desired depth in the photonic semiconductor layer 20 is possible.

The recesses 201 have different depths. The depth of the recesses 201 corresponds to an expansion of the recesses 201 parallel to the emission direction W and transverse to the optical axis R of the resonator. The depths of the recesses 201 differ by at least 10 nm, in particular by at least 100 nm. By means of different depths, an undesired periodicity in the photonic semiconductor layer 20 can be reduced.

A first part of the recesses 201 extends from a side facing away from the semiconductor layer sequence 10 to the first marking layer 205 at a first depth T1 and a second part of the recesses 201 extends from a side facing away from the semiconductor layer sequence 10 to the second marking layer 206 at a second depth T2.

Furthermore, the photonic semiconductor layer 20 comprises a dielectric 203. The dielectric 203 is arranged, for example, around the edges of the recesses 201.

An emission direction E is oriented transverse to the main extension plane of the epitaxial semiconductor layer sequence 10. The emission direction E is the direction in which a majority of the electromagnetic radiation emerges from the optoelectronic semiconductor laser component 1. The first electromagnetic radiation emerges from the photonic semiconductor layer 20 in the emission direction. In other words, the first electromagnetic radiation emerges from the photonic semiconductor layer 20 transversely to the main extension plane of the semiconductor layer sequence 10.

The optoelectronic semiconductor laser component 1 also comprises a conversion element 30, which is configured to convert the first electromagnetic radiation into a second electromagnetic radiation of a second wavelength range. The conversion element 30 is arranged downstream of the epitaxial semiconductor layer sequence 10 in the emission direction E. A contact layer 40 is arranged between the conversion element 30 and the photonic semiconductor layer 20. The contact layer 40 is formed with an electrically conductive material, preferably an ITO. The contact layer 40 is radiation permeable for the first electromagnetic radiation.

The conversion element 30 is designed as an “on-chip” converter and is arranged directly on the contact layer 40. For example, a radiation permeable connecting means is arranged between the contact layer 40 and the conversion element 30. The connecting means comprises, for example, one of the following materials: silicone, transparent glass solder, dielectric. For example, the connecting layer is formed with SiO₂ and is set up for a direct bonding method.

This enables particularly good cooling of the conversion element 30. It is also possible to apply the material of the conversion element 30 directly to the contact layer 40. For example, the conversion element 30 is deposited on the contact layer 40 by spraying, screen printing or sedimentation.

The conversion element 30 causes a conversion of the first electromagnetic radiation to longer wavelengths. A mixed radiation, comprising a part of the first electromagnetic radiation and a part of the second electromagnetic radiation, emerges from the optoelectronic semiconductor laser component 1. The mixed radiation produces a white color impression in an observer.

The semiconductor layer sequence 10 is arranged between the photonic semiconductor layer 20 and a reflector 60. The reflector 60 comprises a plurality of first reflective layers 601 and a plurality of second reflective layers 602. The first reflective layers 601 have a different refractive index from the second reflective layers 602. In particular, the first and second reflective layers 601, 602 are arranged in an alternating order to form a Distributed Bragg Reflector (DBR) for the first electromagnetic radiation.

The reflector 60 is connected to a carrier 80 by means of a connecting layer 70. The carrier 80 is formed with one of the following materials: Diamond, Si, Ge, SiC, AlN, Direct Bonded Copper (DBC). Preferably, the carrier 80 is mechanically self-supporting and provides the optoelectronic semiconductor laser component 1 with sufficient mechanical stability.

The optoelectronic semiconductor laser component 1 is free of a growth substrate 90 and the conversion element 30 is arranged on a side of the epitaxial semiconductor layer sequence opposite the carrier 80. The absence of a growth substrate 90 results in a particularly undisturbed emission of the first electromagnetic radiation.

For electrical contacting, the optoelectronic semiconductor laser component 1 further comprises a first electrode 51 and a second electrode 52. The electrodes 51, 52 are formed with a metal. The first electrode 51 is arranged directly on the contact layer 40. Preferably, the first electrode 51 surrounds the edge of the conversion element 30. For example, the first electrode 51 forms an exit aperture for the electromagnetic radiation emerging from the optoelectronic semiconductor laser component 1. The second electrode 52 is arranged at the second semiconductor region 102.

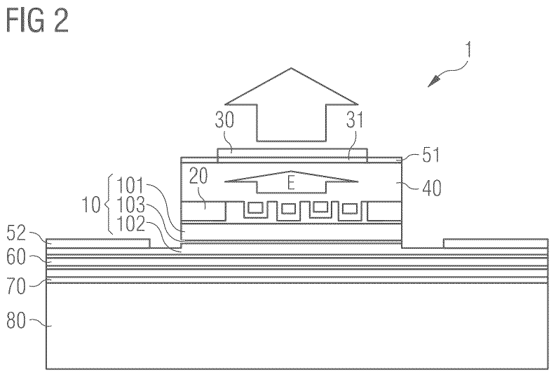

FIG. 2 shows a schematic sectional view of an optoelectronic semiconductor laser component 1 described here according to a second exemplary embodiment. The second exemplary embodiment essentially corresponds to the first exemplary embodiment shown in FIG. 1. In addition, the second exemplary embodiment comprises a wavelength-selective filter element 31. The filter element 31 is arranged between the semiconductor layer sequence 10 and the conversion element 30. The filter element 31 has a higher permeability for the first electromagnetic radiation than for the second electromagnetic radiation. In particular, the filter element 31 is permeable for the first electromagnetic radiation and reflective for the second electromagnetic radiation. Advantageously, a proportion of the second electromagnetic radiation in an emitted mixed radiation is thus increased.

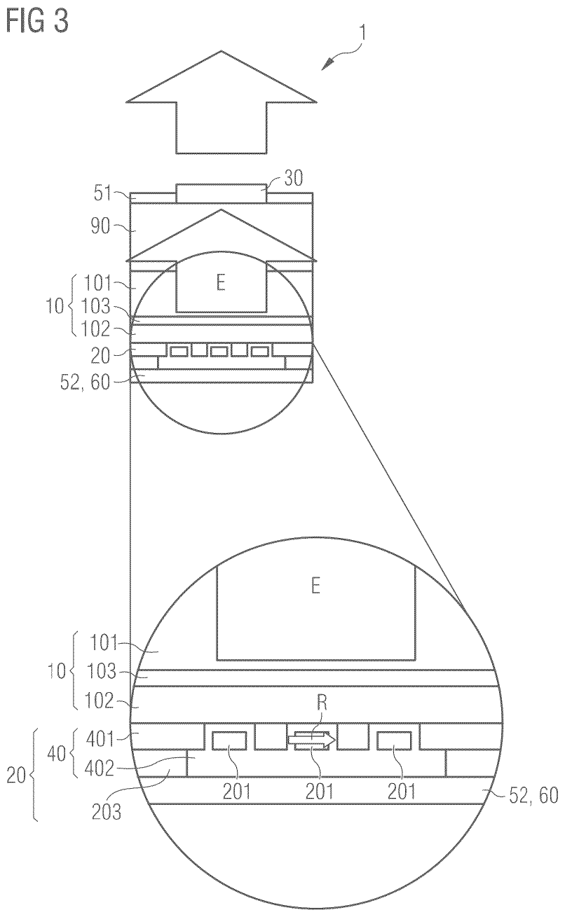

FIG. 3 shows a schematic sectional view of an optoelectronic semiconductor laser component 1 described here according to a third exemplary embodiment. The third exemplary embodiment essentially corresponds to the first exemplary embodiment shown in FIG. 1. In contrast to the first exemplary embodiment, the optoelectronic semiconductor laser component 1 comprises a growth substrate 90 arranged directly on the semiconductor layer sequence 10. The layers of the epitaxial semiconductor layer sequence 10 are grown on the growth substrate 90. The growth substrate 90 is preferably formed with the material of the semiconductor layer sequence 10.

The growth substrate 90 is formed with sapphire or a nitride semiconductor compound material, preferably with gallium nitride. The nitride semiconductor compound material advantageously has large pores. For example, pores and fine channels can be introduced into the growth substrate 90 by means of suitable etching solutions.

In particular, the growth substrate 90 is permeable to the first electromagnetic radiation. The growth substrate 90 has a thickness of at most 100 μm, in particular of at most 50 μm. Preferably, the growth substrate 90 is thinned to this thickness and has traces of an ablation process on the side opposite the semiconductor layer sequence 10. A thin growth substrate 90 enables particularly unhindered transmission of the first electromagnetic radiation through the growth substrate 90.

The conversion element 30 is arranged on the growth substrate 30. In other words, the growth substrate 90 is arranged between the semiconductor layer sequence 10 and the conversion element 30. The conversion element 30 has, for example, a thickness of at least 10 μm, preferably of at least 50 μm and particularly preferably of at least 100 μm. A particularly thick conversion element 30 has a mechanically stabilizing effect and can thus enable the use of a thinner growth substrate 90.

In contrast to the first exemplary embodiment, the photonic semiconductor layer 20 is arranged on the side of the second semiconductor region 102 on the semiconductor layer sequence 10. The photonic semiconductor layer 20 comprises a dielectric 203 and a contact layer 40. The contact layer 40 is formed with an electrically conductive material, for example ITO. The contact layer 40 has a first contact region 401 and a second contact region 402.

The first contact region 401 is formed with a different material from the second contact region 402. For example, the first and second contact regions 401, 402 are formed with different TCO materials. The first contact region 401 is arranged in the main extension plane of the resonator in the photonic semiconductor layer 20. The second contact region 402 is arranged on a side of the recesses 201 facing away from the semiconductor layer sequence 10 and extends from a side of the photonic semiconductor layer 20 facing away from the semiconductor layer sequence 10 into the recesses 201. The second contact region 402 extends in the recesses 201 to the second semiconductor region 102 of the semiconductor layer sequence 10.

In particular, the first contact region 401 has a higher optical radiation permeability for the first electromagnetic radiation than the second contact region 402. A high radiation permeability advantageously results in low optical losses in the resonator of the photonic semiconductor layer 20.

In particular, the second contact region 402 has a higher electrical conductivity than the first contact region 401. A high electric conductivity results in an advantageously low electrical resistance for the injection of charge carriers into the second semiconductor region 102.

For electrical contacting, the optoelectronic semiconductor laser component 1 further comprises a first electrode 51 and a second electrode 52. The electrodes 51, 52 are formed with a metal. The first electrode 51 is arranged directly on the growth substrate 90. Preferably, the first electrode 51 surrounds the edge of the conversion element 30. For example, the first electrode 51 forms an exit aperture for the electromagnetic radiation emerging from the optoelectronic semiconductor laser component 1.

The second electrode 52 is arranged at the photonic semiconductor layer 20. The second electrode 52 is formed with a metal that has a high reflectivity for the first electromagnetic radiation. The second electrode 52 thus forms a reflector 60 for the first electromagnetic radiation.

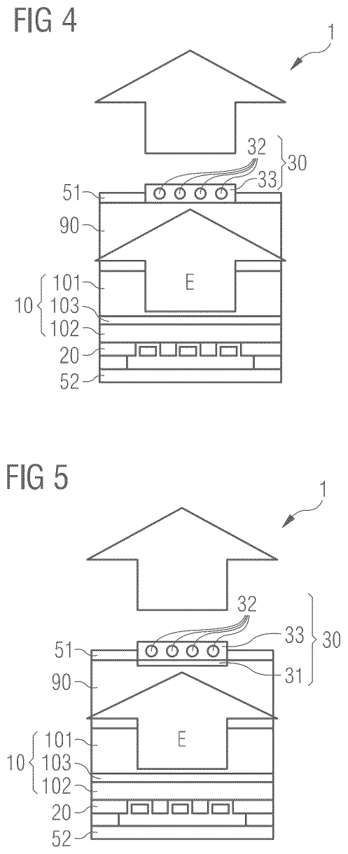

FIG. 4 shows a schematic sectional view of an optoelectronic semiconductor laser component 1 described here according to a fourth exemplary embodiment. The fourth exemplary embodiment essentially corresponds to the third exemplary embodiment shown in FIG. 3. In contrast to the third exemplary embodiment, the conversion element 30 comprises a plurality of conversion regions 32 embedded in a shaped body 33. The conversion regions 32 are formed with quantum dots. Quantum dots are particularly easy to introduce into small pores of a porous material. The shaped body 33 is formed with a radiation permeable material. In particular, the shaped body 33 is a porous material into the pores of which the conversion regions 32 penetrate. For example, the shaped body 33 is formed with a ceramic, a polysiloxane or a semiconductor material. Preferably, the shaped body 33 is formed with gallium nitride.

FIG. 5 shows a schematic sectional view of an optoelectronic semiconductor laser component 1 described here according to a fifth exemplary embodiment. The fifth exemplary embodiment essentially corresponds to the fourth exemplary embodiment shown in FIG. 4. In addition, the fifth exemplary embodiment comprises a wavelength-selective filter element 31. The filter element 31 is arranged between the semiconductor layer sequence 10 and the conversion element 30. The filter element 31 has a higher permeability for the first electromagnetic radiation than for the second electromagnetic radiation. In particular, the filter element 31 is permeable for the first electromagnetic radiation and reflective/reflecting for the second electromagnetic radiation. Advantageously, a proportion of the second electromagnetic radiation in an emitted mixed radiation is thus increased.

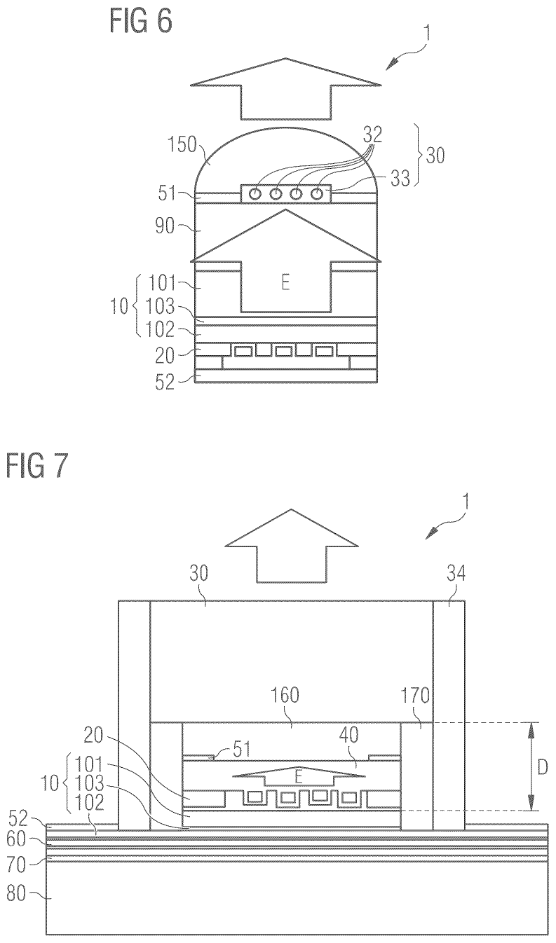

FIG. 6 shows a schematic sectional view of an optoelectronic semiconductor laser component 1 described here according to a sixth exemplary embodiment. The sixth exemplary embodiment essentially corresponds to the fourth exemplary embodiment shown in FIG. 4. In addition, the sixth exemplary embodiment comprises an optical element 150. The optical element 150 is, for example, a lens for beam shaping. In particular, the optical element 150 is a collimating lens for the electromagnetic radiation emerging from the semiconductor laser component 1. The optical element 150 is arranged downstream of the conversion element in the emission direction E.

FIG. 7 shows a schematic sectional view of an optoelectronic semiconductor laser component 1 described here according to a seventh exemplary embodiment. The seventh exemplary embodiment essentially corresponds to the first exemplary embodiment shown in FIG. 1. In contrast to the first exemplary embodiment, the conversion element 30 is designed as a near-to-chip converter. In other words, the conversion element 30 is arranged at a distance D from the semiconductor layer sequence 10.

The conversion element 30 comprises a frame body 34, which is mounted on the optoelectronic semiconductor laser component 1 via an alignment element 170. The frame body 34 preferably surrounds the conversion element 30 at the edges. For example, the frame body is formed with metal. In particular, the alignment element 170 is in contact with the semiconductor layer sequence 10. The alignment element 170 comprises, for example, a body produced by means of additive manufacturing. Preferably, the alignment element 170 is formed with metal.

The conversion element 30 is not in direct contact with the semiconductor layer sequence 10 and can have a particularly large expansion in the emission direction E. In particular, the conversion element 30 has an expansion in the emission direction E of more than 100 μm and preferably of more than 1000 μm.

The distance D of the conversion element from the semiconductor layer sequence 10 in the emission direction E is preferably within the coherence length of the first electromagnetic radiation. In particular, the distance D is at least 1 μm, preferably at least 10 μm and particularly preferably at least 50 μm. Advantageously, cooling of the conversion element 30 can thus take place independently of cooling of the semiconductor layer sequence 10.

A cavity 160 is formed between the semiconductor layer sequence 10 and the conversion element 30. For example, the cavity 160 is filled with a radiation permeable material whose refractive index is between the refractive indices of the contact layer 40 and the conversion element 30.

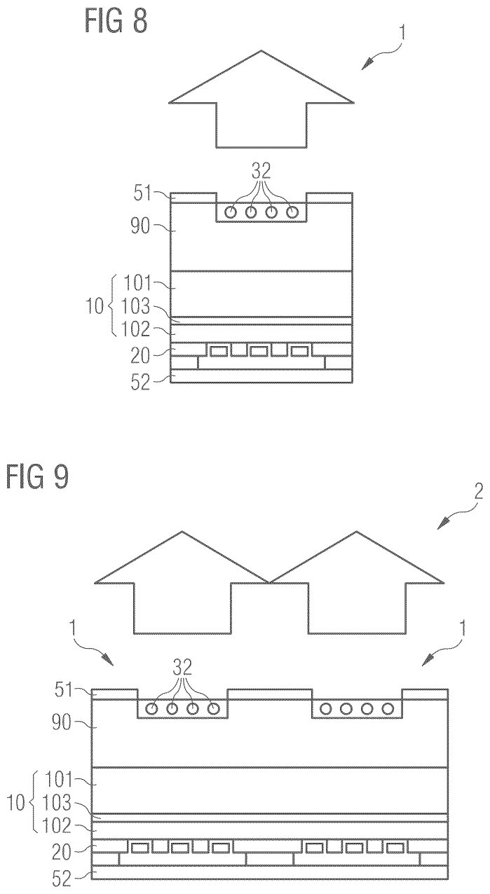

FIG. 8 shows a schematic sectional view of an optoelectronic semiconductor laser component 1 described here according to an eighth exemplary embodiment. The eighth exemplary embodiment essentially corresponds to the fourth exemplary embodiment shown in FIG. 4. In contrast to the fourth exemplary embodiment, the conversion element 30 is at least partially embedded in the growth substrate 90. The growth substrate 90 is formed with a porous material. For example, the pores are generated in the growth substrate 90 using an etching process. Porous means here and in the following a material with pores of an average size of at least 10 nm, preferably of at least 100 nm, particularly preferably of at least 200 nm.

A plurality of conversion regions 32 contain quantum dots embedded in pores of the growth substrate 90. A shaped body can thus be dispensed with. Advantageously, this eliminates a refractive index jump between a shaped body 31 and the growth substrate 90. Furthermore, embedding in the growth substrate 90 enables particularly good cooling of the conversion regions 32.

FIG. 9 shows a schematic sectional view of an optoelectronic arrangement 2 described herein according to a first exemplary embodiment. The optoelectronic arrangement 2 comprises two optoelectronic semiconductor laser components 1. The optoelectronic semiconductor laser components 1 essentially correspond to the eighth exemplary embodiment shown in FIG. 8. The semiconductor laser components 1 comprise a continuous epitaxial semiconductor layer sequence 10. The formation of a plurality of semiconductor laser components 1 in an epitaxial semiconductor layer sequence 10 enables particularly simple manufacture of an optoelectronic arrangement 2 with a high density of semiconductor laser components 1.

The wavelengths of the second electromagnetic radiation of the semiconductor laser components 1 differ from each other by at least 5 nm, preferably by at least 10 nm. Unwanted interference effects, such as speckles, can thus be specifically reduced.

In particular, the semiconductor laser components 1 can be individually controlled. For example, an arrangement 2 comprises at least three semiconductor laser components 1, with one semiconductor laser component emitting a second electromagnetic radiation in the red wavelength range, one semiconductor laser component emitting a second electromagnetic radiation in the green wavelength range and one semiconductor laser component emitting a second electromagnetic radiation in the blue wavelength range. Advantageously, an RGB pixel can be produced in this way. In particular, several optoelectronic semiconductor laser components 1 are arranged in an array.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1. An optoelectronic semiconductor laser component comprising
an epitaxial semiconductor layer sequence having an active region configured to generate a first electromagnetic radiation of a first wavelength range,
a photonic semiconductor layer forming a two-dimensional photonic crystal and configured to form a resonator for the first electromagnetic radiation, and
a conversion element configured to convert the first electromagnetic radiation into a second electromagnetic radiation of a second wavelength range, wherein
the first electromagnetic radiation propagates within the resonator parallel to a main extension plane of the epitaxial semiconductor layer sequence,
an emission direction is oriented transversely to the main extension plane of the epitaxial semiconductor layer sequence,
the first electromagnetic radiation emerges from the photonic semiconductor layer in the emission direction, and
the first wavelength range is in the blue or ultraviolet spectral range.

2. The optoelectronic semiconductor laser component according to claim 1, wherein
a growth substrate is arranged directly on the semiconductor layer sequence, and
the conversion element is arranged on the growth substrate on a side of the growth substrate facing away from the semiconductor layer sequence.

3. The optoelectronic semiconductor laser component according to claim 2, wherein the growth substrate has pores at least in some sections.

4. The optoelectronic semiconductor laser component according to claim 2, wherein the growth substrate has a thickness of at most 100 μm, in particular of at most 50 μm.

5. The optoelectronic semiconductor laser component according to claim 2, wherein the conversion element is at least partially embedded in the growth substrate.

6. The optoelectronic semiconductor laser component according to claim 2, wherein the growth substrate is formed with a III/V compound semiconductor material, preferably with a nitride compound semiconductor material and particularly preferably with GaN.

7. The optoelectronic semiconductor laser component according to claim 1, wherein
the photonic semiconductor layer comprises a contact layer having a first contact region and a second contact region, and wherein
the first contact region is formed with a material different from the second contact region.

8. The optoelectronic semiconductor laser component according to claim 1, wherein
the semiconductor layer sequence comprises a first semiconductor region of a first conductivity and a second semiconductor region of a second conductivity,
the second semiconductor region has a p-type conductivity, and
the second semiconductor region is arranged between the active region and the photonic semiconductor layer.

9. The optoelectronic semiconductor laser component according to claim 1, wherein
the epitaxial semiconductor layer sequence is arranged on a carrier,
the optoelectronic semiconductor laser component is free of a growth substrate, and
the conversion element is arranged on a side of the epitaxial semiconductor layer sequence opposite the carrier.

10. The optoelectronic semiconductor laser component according to claim 9, wherein
the photonic semiconductor layer comprises a radiation permeable functional layer and a plurality of recesses, and wherein
the functional layer is arranged at least partially between the recesses and the semiconductor layer sequence.

11. The optoelectronic semiconductor laser component according to claim 10, wherein the functional layer is formed with a semiconductor material.

12. The optoelectronic semiconductor laser component according to claim 10, wherein the functional layer has at least a first marking layer.

13. The optoelectronic semiconductor laser component according to claims 9, wherein
the semiconductor layer sequence comprises a first semiconductor region of a first conductivity and a second semiconductor region of a second conductivity,
the first semiconductor region has an n-conductivity, and
the first semiconductor region is arranged between the active region and the photonic semiconductor layer.

14. The optoelectronic semiconductor laser component according to claim 9, wherein the conversion element is arranged at a distance from the semiconductor layer sequence.

15. The optoelectronic semiconductor laser component according to claim 10, wherein depths of the recesses differ by at least 10 nm, in particular by at least 100 nm.

16. The optoelectronic semiconductor laser component according to claim 1, wherein the conversion element comprises a plurality of conversion regions embedded in a shaped body.

17. The optoelectronic semiconductor laser component according to claim 1, wherein a wavelength-selective filter element is arranged between the semiconductor layer sequence and the conversion element.

18. (canceled)

19. An optoelectronic arrangement comprising:
at least two optoelectronic semiconductor laser components according to claim 1, wherein
the semiconductor laser components have a contiguous epitaxial semiconductor layer sequence.

20. The optoelectronic arrangement according to claim 19, wherein the wavelengths of the second electromagnetic radiation of the semiconductor laser components differ from one another by at least 5 nm, preferably by at least 10 nm.

21. An optoelectronic semiconductor laser component comprising:
an epitaxial semiconductor layer sequence having an active region configured to generate a first electromagnetic radiation of a first wavelength range,
a photonic semiconductor layer forming a two-dimensional photonic crystal and configured to form a resonator for the first electromagnetic radiation, and
a conversion element configured to convert the first electromagnetic radiation into a second electromagnetic radiation of a second wavelength range, wherein
the first electromagnetic radiation propagates within the resonator parallel to a main extension plane of the epitaxial semiconductor layer sequence,
an emission direction is oriented transversely to the main extension plane of the epitaxial semiconductor layer sequence,
the first electromagnetic radiation emerges from the photonic semiconductor layer in the emission direction,
the first wavelength range is in the blue or ultraviolet spectral range,
a growth substrate is arranged directly on the semiconductor layer sequence, and
the conversion element is arranged on the growth substrate on a side of the growth substrate facing away from the semiconductor layer sequence.
